(19) United States
(12) Patent Application Publication
(10) Pub. No.: US 2012/0235171 A1
(43) Pub. Date: Sep. 20, 2012

(54) ORGANIC LIGHT EMITTING DIODE DISPLAY

(76) Inventors: Yong-Tak KIM, Yongin-City (KR); Yoon-Hyeung Cho, Yongin-City (KR); Min-Ho Oh, Yongin-City (KR); Byoung-Duk Lee, Yongin-City (KR); So-Young Lee, Yongin-City (KR); Sang-Hwan Cho, Yongin-City (KR); Yun-Ah Chung, Yongin-City (KR); Seung-Yong Song, Yongin-City (KR); Jong-Hyuk Lee, Yongin-City (KR)

(21) Appl. No.: 13/292,770

(22) Filed: Nov. 9, 2011

(30) Foreign Application Priority Data
Mar. 18, 2011 (KR) 10-2011-0024566

(51) Int. Cl. H01L 51/52; H01L 51/56

(52) U.S. Cl. 257/88; 438/26; 257/40; 257/E51.018

(57) ABSTRACT

An organic light emitting diode display includes a substrate having a plurality of organic light emitting elements thereon and a thin film encapsulation layer on the substrate. The thin film encapsulation layer covers the organic light emitting elements, and the thin film encapsulation layer includes a first porous inorganic layer and a second inorganic layer on the first porous inorganic layer.

### RELATED APPLICATIONS

This application claims priority to and the benefit of Korean Patent Application No. 10-2011-0024566 filed in the Korean Intellectual Property Office on Mar. 18, 2011, the entire contents of which are incorporated herein by reference.

### BACKGROUND

An organic light emitting diode display (OLED) has a self luminance characteristic and may not require a separate light source, unlike a liquid crystal display (LCD) device. As such, a thickness and/or weight of the OLED may be reduced. The OLED display may exhibit quality characteristics such as low power consumption, high luminance, and high response speed. Therefore, the OLED display has received attention as a next-generation display device.

### SUMMARY

Embodiments may be realized by providing an organic light emitting diode display that includes a substrate on which a plurality of organic light emitting elements are formed, and a thin film encapsulation layer formed on the substrate and covering the organic light emitting elements, wherein the thin film encapsulation layer includes a first porous inorganic layer, and a second inorganic layer formed on the first porous inorganic layer.

The first porous inorganic layer may be made of silicon carbon nitride (SiCN), and the second inorganic layer may be made of silicon nitride (SiN).

A plurality of first porous inorganic layers and a plurality of second inorganic layers may be alternately formed.

A layer density of the first porous inorganic layer may be greater than about 1.4 g/cm³ and less than about 1.8 g/cm³.

A layer density of the second inorganic layer may be greater than about 2.0 g/cm³ and less than about 3.5 g/cm³.

A refractive index of the first porous inorganic layer may be greater than about 1.5 and less than about 1.75.

A thickness of the first porous inorganic layer may be about 0.5 to about 1.5 μm.

A thickness of the second inorganic layer may be about 0.5 to about 1.5 μm.

Embodiments may also be realized by providing a method for manufacturing an organic light emitting diode display that includes forming a first porous inorganic layer for covering a plurality of organic light emitting elements on a substrate on which the organic light emitting elements are formed, and forming a second inorganic layer for covering the first porous inorganic layer.

The first porous inorganic layer may be made of silicon carbon nitride (SiCN), and the second inorganic layer may be made of silicon nitride (SiN).

The first porous inorganic layer may be formed by mixing materials including SiH₄, NH₃, N₂, H₂, and C₂H₂.

The second inorganic layer may be formed by mixing materials including SiH₄, NH₃, N₂, and H₂.

### BRIEF DESCRIPTION OF THE DRAWINGS

Features will become apparent to those of ordinary skill in the art by describing in detail exemplary embodiments with reference to the attached drawings in which:

FIG. 1 illustrates an equivalent circuit of an organic light emitting diode (OLED) display, according to an exemplary embodiment.

FIG. 2 illustrates a partially enlarged cross-sectional view of an organic light emitting diode (OLED), according to an exemplary embodiment.

FIGS. 3 and 4 illustrate sequentially stages of an exemplary method of manufacturing the organic light emitting diode (OLED) display illustrated in FIG. 2.

FIG. 5A illustrates an image of an organic light emitting diode (OLED) display turned on when 140 hours have passed after a first inorganic layer was formed in the case in which the first inorganic layer is formed on a second pixel electrode.

FIG. 5B illustrates an image of an organic light emitting diode (OLED) display turned on when 410 hours have passed after a first inorganic layer was formed in the case in which the first inorganic layer is formed on a second pixel electrode.

FIG. 6A illustrates an image of an organic light emitting diode (OLED) display turned on when 20 hours have passed after a second inorganic layer was formed in the case in which an organic layer and the second inorganic layer are sequentially formed on the second pixel electrode.

FIG. 6B illustrates an image of an organic light emitting diode (OLED) display turned on when 92 hours have passed after a second inorganic layer was formed in the case in which an organic layer and the second inorganic layer are sequentially formed on the second pixel electrode.

FIG. 7A illustrates an image of an organic light emitting diode (OLED) display turned on when 140 hours have passed after a second inorganic layer was formed in the case in which a first porous inorganic layer and a second inorganic layer are sequentially formed on the second pixel electrode.

FIG. 7B illustrates an image of an organic light emitting diode (OLED) display turned on when 410 hours have passed after a second inorganic layer was formed in the case in which a first porous inorganic layer and a second inorganic layer are sequentially formed on the second pixel electrode.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when an element is referred to as being “on” another element, it can be directly on the other element, or intervening elements may also be present. Further, it will be understood that when an element is referred to as being “under” another element, it can be directly under, and one or more intervening elements may also be present. In addition, it will also be understood that when an element is referred to as being “between” two elements, it can be the only element between the two elements, or one or more intervening elements may also be present. Like reference numerals refer to like elements throughout.

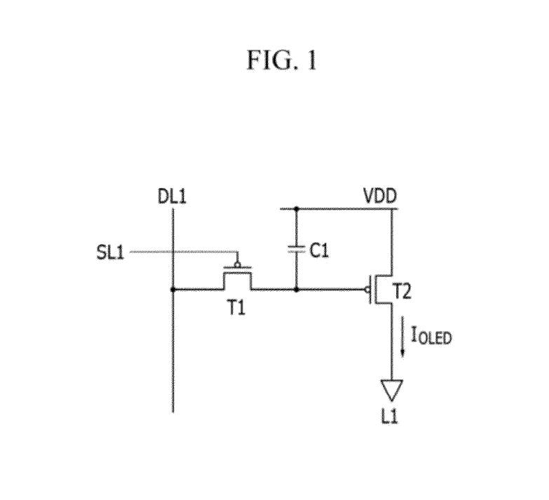

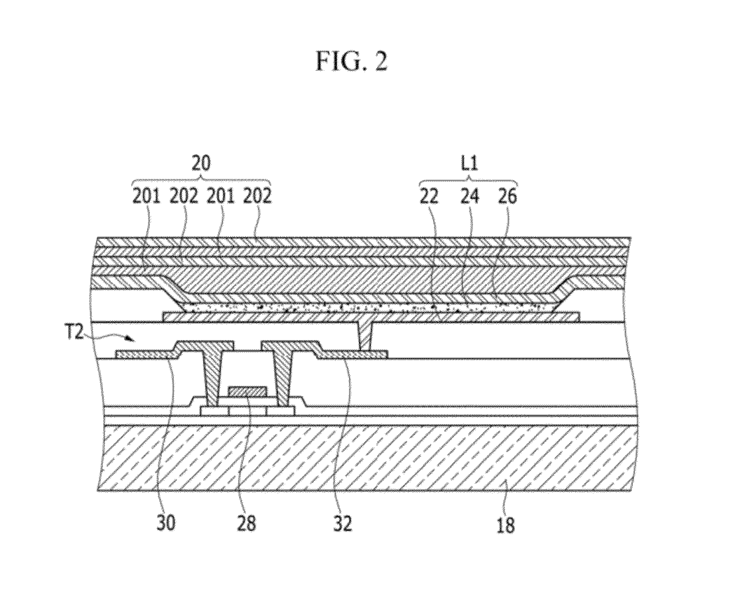

FIG. 1 illustrates a circuit diagram of a pixel in an organic light emitting diode (OLED) display, according to an exemplary embodiment. FIG. 2 illustrates a partially enlarged cross-sectional view of a pixel of an organic light emitting diode (OLED) that includes the circuit diagram of FIG. 1.

As shown in FIG. 1 and FIG. 2, a pixel of the organic light emitting diode (OLED) display may include an organic light emitting element L1 and a driving circuit. The organic light emitting element L1 may include a first pixel electrode 22, e.g., a hole injection electrode, an organic emission layer 24, and a second pixel electrode, e.g., an electron injection electrode 26.

The organic emission layer 24 may include organic layers (not shown) for transmitting the holes or carriers of the electrons to an emission layer (not shown). The emission layer may be for actually emitting light. The organic layers may be, e.g., a hole injection layer (HIL) and a hole transport layer (HTL). The HTL may be provided between the first pixel electrode 22 and the emission layer. An electron injection layer (EIL) and an electron transport layer (ETL) may be provided between the second pixel electrode 26 and the emission layer.

A driving circuit may include at least two thin film transistors T1 and T2, as illustrated in FIGS. 1 and 2, respectively, and at least one storage capacitor C1, as illustrated in FIG. 1. For example, the thin film transistor may include a switching transistor T1 and a driving transistor T2.

The switching transistor T1 may be connected to a scan line SL1 and a data line DL1. The switching transistor T1 may transmit a data voltage input to the data line DL1 to the driving transistor T2 according to a switching voltage input to the scan line SL1. The storage capacitor C1 may be connected to the switching transistor T1 and a power supply line VDD. The storage capacitor C1 may store a voltage that corresponds to a difference between the voltage provided by the switching transistor T1 and the voltage provided to the power supply line VDD.

The driving transistor T2 may be connected to the power supply line VDD and the storage capacitor C1 to supply an output current (I_{OLED}). The output current (I_{OLED}) may be proportional to a square of the difference between the voltage stored in the storage capacitor C1 and a threshold voltage to the organic light emitting element L1. The organic light emitting element L1 may emit light according to the output current (I_{OLED}). The driving transistor T2 may include a gate electrode 28, a source electrode 30, and a drain electrode 32. The first pixel electrode 22 of the organic light emitting element L1 may be connected to the drain electrode 32 of the driving transistor T2. The configuration of the pixel is not restricted to the above description and is variable in many ways.

Referring to FIG. 2, a thin film encapsulation layer 20 may be formed on a plurality of organic light emitting elements that are formed on a substrate 18. The thin film encapsulation layer 20 may cover the organic light emitting element L1 and the driving transistor T2, e.g., the organic light emitting element L1 and the driving transistor T2 may be under the thin film encapsulation layer 20. The encapsulation layer 20 may be formed on the driving circuit formed on the substrate 18 to, e.g., seal and/or protect the organic light emitting element and the driving circuit.

The thin film encapsulation layer 20 may include first porous inorganic layers 201 and second inorganic layers 202 that are alternately stacked. For example, one second inorganic layer 202 may be between two first porous inorganic layers 201. FIG. 2 exemplifies the case in which two first porous inorganic layers 201 and two second inorganic layers 202 are alternately stacked to form the thin film encapsulation layer 20. However, embodiments are not limited thereto, e.g., the encapsulation layer 20 may include one or more than two first porous inorganic layers 201 and one or more than two second inorganic layers 202.

According to an exemplary embodiment, the first porous inorganic layer 201 may be formed with, e.g., made entirely of, silicon carbon nitride (SiCN). The second inorganic layer 202 may be formed with, e.g., made entirely of, silicon nitride (SiN).

A layer density of the first porous inorganic layer 201 may be greater than about 1.4 g/cm³ and less than about 1.8 g/cm³. However embodiments of the range for the layer density are not limited thereto e.g., the layer density may be about 1.5 g/cm³ and to about 1.8 g/cm³. Without intending to be bound by this theory, when the layer density of the first porous inorganic layer 201 is less than about 1.4 g/cm³, the external moisture and oxygen may easily permeate the first porous inorganic layer 201. When the layer density of the second inorganic layer 202 is greater than about 1.8 g/cm³, the stress of the layer may be increased to cause the layer to become, e.g., loose. The layer density of the first porous inorganic layer 201 may correspond to the density of silicon carbon nitride (SiCN) in the first porous inorganic layer 201.

The layer density of the second inorganic layer 202 may be greater than about 2.0 g/cm³ and less than about 3.5 g/cm³. However embodiments of the range for the layer density are not limited thereto e.g., the layer density may be about 2.5 g/cm³ and to about 3.0 g/cm³. Without intending to be bound by this theory, when the layer density of the second inorganic layer 202 is less than about 2.0 g/cm³, the external moisture and oxygen may easily permeate it. When the layer density of the second inorganic layer 202 is greater than about 3.5 g/cm³ the stress of the layer may be increased so that the layer may become loose.

A refractive index of the first porous inorganic layer 201 may be greater than about 1.5 and less than about 1.75. However, embodiments of the range for the refractive index are not limited thereto, e.g., the refractive index may be about 1.6 to about 1.7. Without intending to be bound by this theory, when the refractive index of the first porous inorganic layer 201 is greater than about 1.75, viewing angle and visibility may be deteriorated.

The thickness of the first porous inorganic layer 201 may be from about 0.5 μm to about 1.5 μm. However, embodiments of the range for thickness are not limited thereto, e.g., the thickness may be from about 1.0 μm to about 1.25 μm. Without intending to be bound by this theory, when the thickness of the first porous inorganic layer 201 is less than about 0.5 μm, it may be difficult to cover the particles so a dark spot may be easily generated by the particle. When the thickness of the first porous inorganic layer 201 is greater than about 1.5 μm, the stress of the layer may be increased so that the layer may easily become loose and/or the processing time may be increased.

The thickness of the second inorganic layer 202 may be from about 0.5 to about 1.5 μm. However, embodiments of the range for thickness are not limited thereto, e.g., the thickness may be from about 1.0 μm to about 1.25 μm. Without intending to be bound by this theory, when the thickness of the second inorganic layer 202 is less than about 0.5 μm, external moisture and oxygen may easily permeate into it. When the thickness of the second inorganic layer 202 is greater than about 1.5 μm, the stress of the layer may be increased so that the layer may easily become loose.

According to exemplary embodiments, the first porous inorganic layer 201 may reduce the stress of the layer. The first porous inorganic layer 201 may reduce and/or prevent the generation of dark spots caused by particles generated by deposition of layers, e.g., deposition of thin film encapsulation layer 20. The second inorganic layer 202 may control permeation of external moisture and oxygen.

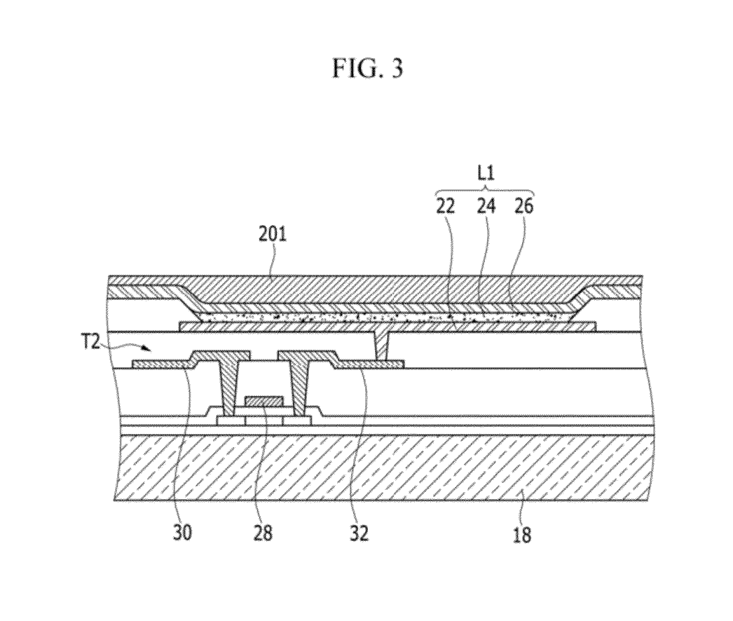

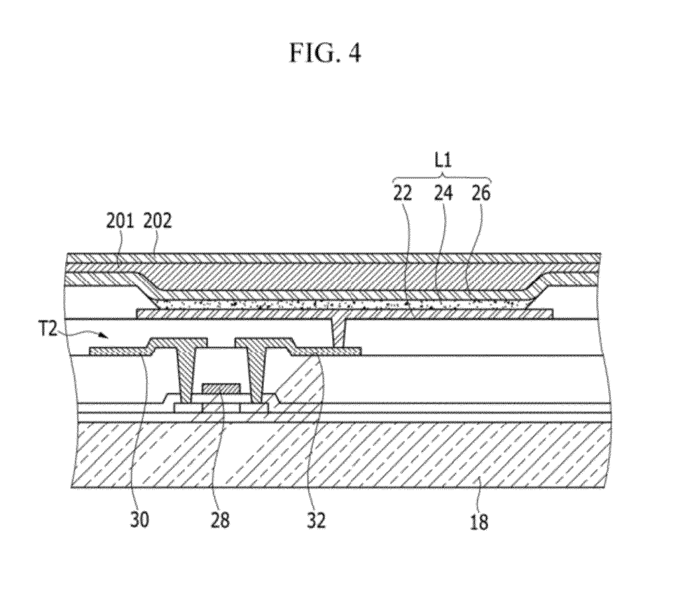

FIG. 3 and FIG. 4 illustrate an exemplary method of manufacturing an organic light emitting diode (OLED) display as illustrated in FIG. 2. FIG. 3 and FIG. 4 illustrate sequentially cross-sectional views of stages in an exemplary method of manufacturing the organic light emitting diode display.

Referring to FIG. 3, a first porous inorganic layer 201 for covering an organic light emitting element may be formed on the substrate 18 on which a plurality of organic light emitting elements are previously formed. The first porous inorganic layer 201 may be made of silicon carbon nitride (SiCN), The silicon carbon nitride may be formed by adding acetylene (C₂H₂) to silane (SiH₄), ammonia (NH₃), nitrogen (N₂), and hydrogen (H₂), and mixing them under a high temperature and high pressure plasma condition. The first porous inorganic layer 201 may be formed directly on the electron injection electrode 26.

Referring to FIG. 4, a second inorganic layer 202 made of silicon nitride (SiN) may be formed on, e.g., directly on, the first porous inorganic layer 201. The second inorganic layer 202 may be formed by mixing SiH₄, NH₃, N₂, and H₂ under the high temperature and high pressure plasma condition.

According to an exemplary embodiment, the first porous inorganic layer 201 and the second inorganic layer 202 may be sequentially deposited, e.g., as illustrated in FIG. 2.

As shown in the experimental examples of Table 1, the first porous inorganic layer 201 may be formed by adding C₂H₂ to SiH₄, NH₃, N₂, and H₂.

TABLE 1

| | SiH₄ | NH₃ | N₂ | H₂ | C₂H₂ | Power | Pressure | Refractive |
|---|---|---|---|---|---|---|---|---|
| | (sccm) | (sccm) | (sccm) | (sccm) | (sccm) | (W) | (torr) | index (n) |
| Experimental | 250 | 400 | 1500 | 4000 | 50 | 600 | 3 | 1.74 |
| case 1 | | | | | | | | |
| Experimental | 250 | 400 | 1500 | 4000 | 100 | 600 | 3 | 1.75 |
| case 2 | | | | | | | | |
| Experimental | 250 | 400 | 1500 | 4000 | 150 | 600 | 3 | 1.74 |
| case 3 | | | | | | | | |
| Experimental | 250 | 400 | 1500 | 4000 | 200 | 600 | 3 | 1.72 |
| case 4 | | | | | | | | |
| Experimental | 450 | 250 | 1500 | 4000 | 50 | 1200 | 1.8 | 1.61 |
| case 5 | | | | | | | | |
| Experimental | 450 | 250 | 1500 | 4000 | 100 | 1200 | 1.8 | 1.90 |
| case 6 | | | | | | | | |
| Experimental | 450 | 250 | 1500 | 4000 | 150 | 1200 | 1.8 | 1.85 |
| case 7 | | | | | | | | |
| Experimental | 450 | 250 | 1500 | 4000 | 200 | 1200 | 1.8 | 1.87 |
| case 8 | | | | | | | | |

As expressed in the experimental examples 1 to 4 of Table 1, when the radio frequency with the frequency of 13.56 has the power of 600 W, the first porous inorganic layer 201 with a refractive index that is less than 1.75 is formed.

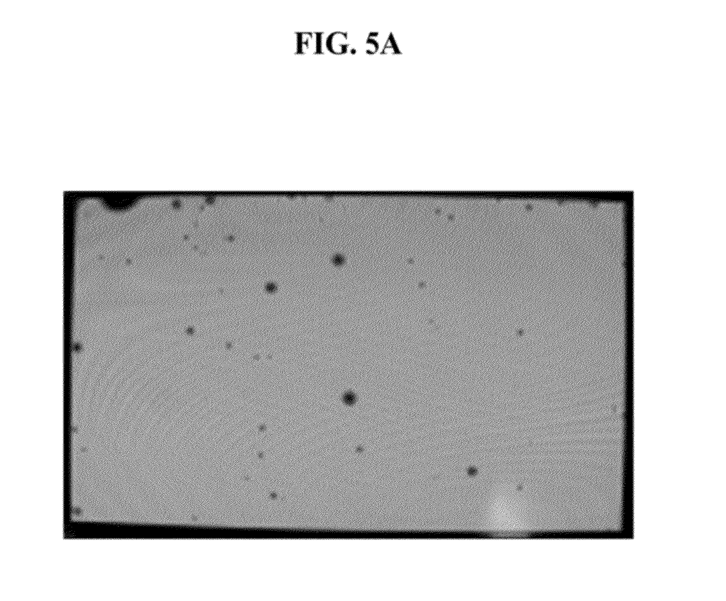

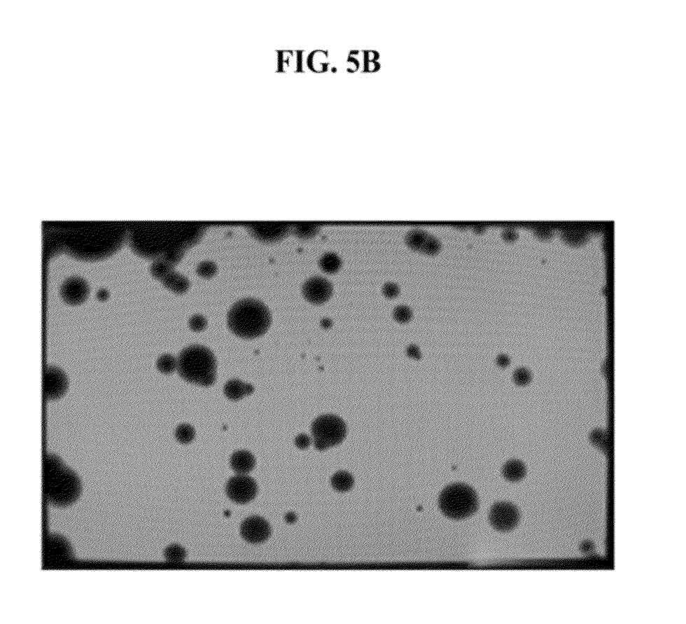

FIG. 5A illustrates an image of an organic light emitting diode (OLED) display turned on when 140 hours have passed after a first inorganic layer was formed in the case in which the first inorganic layer was formed on a second pixel electrode. FIG. 5B illustrates an image of an organic light emitting diode (OLED) display turned on when 410 hours have passed after a first inorganic layer was formed in the case in which the first inorganic layer was formed on a second pixel electrode.

As shown in FIG. 5A and FIG. 5B, it was found that the size of the dark spots is gradually increased as time passes under the high temperature (85° C.) and high moisture (85%) condition after the first inorganic layer was deposited. This is because the sides of the particles are damaged by the moisture and the oxygen having permeated into the sides of the particles when the first inorganic layer was formed. Thus, the dark spots grow quickly.

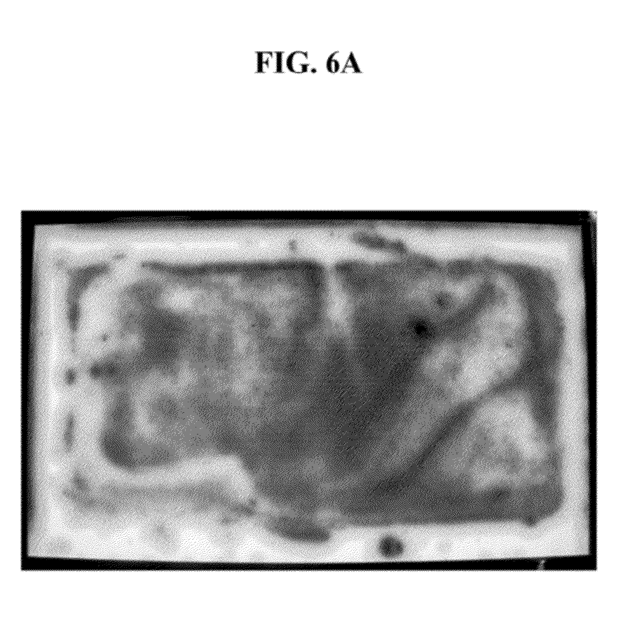

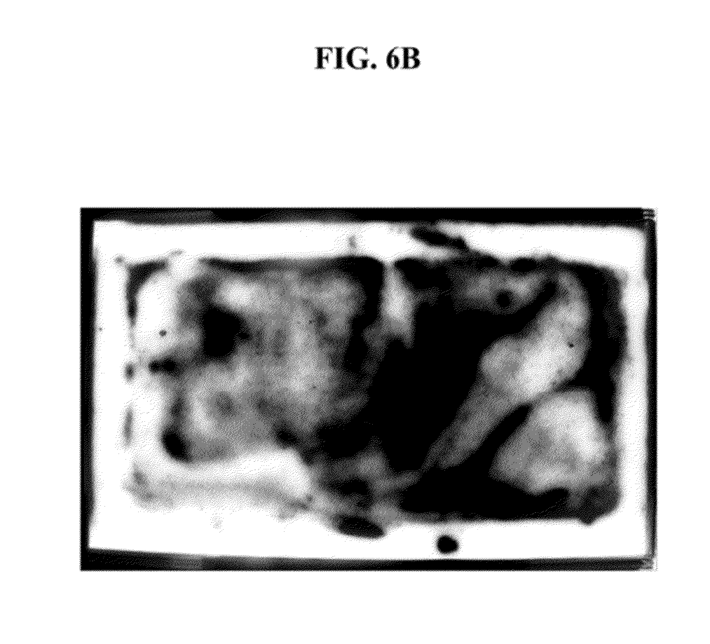

FIG. 6A illustrates an image of an organic light emitting diode (OLED) display turned on when 20 hours have passed after a second inorganic layer was formed in the case in which an organic layer and a second inorganic layer are sequentially formed on a second pixel electrode. FIG. 6B illustrates an image of an organic light emitting diode (OLED) display turned on when 92 hours have passed after a second inorganic layer was formed in the case in which an organic layer and the second inorganic layer were sequentially formed on the second pixel electrode.

As shown in FIG. 6A and FIG. 6B, it was found that the sides of the particles were damaged by moisture and oxygen as time passes under the high temperature (85° C.) and high moisture (85%) condition after the second inorganic layer 202 was deposited. Thus, the size of the dark spots was increased, e.g., gradually increased. This is because the organic layer reduces the stress and is weak in reducing and/or preventing permeation of moisture so the dark spots spread quickly.

However, according to the exemplary embodiments of an organic light emitting diode (OLED) display, the first porous inorganic layer 201 may be formed instead, e.g., first inorganic layer or the organic layer, for reducing stress of the layer while covering the particles to reduce and/or prevent permeation of moisture and oxygen into underlying layers. Thus, reducing the possibility of and/or preventing an increase of the size of the dark spots occurring at the side of the particles.

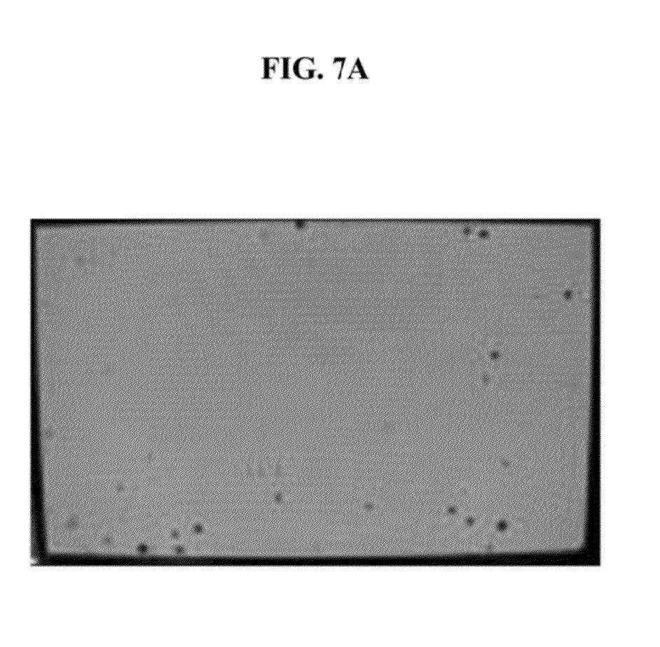

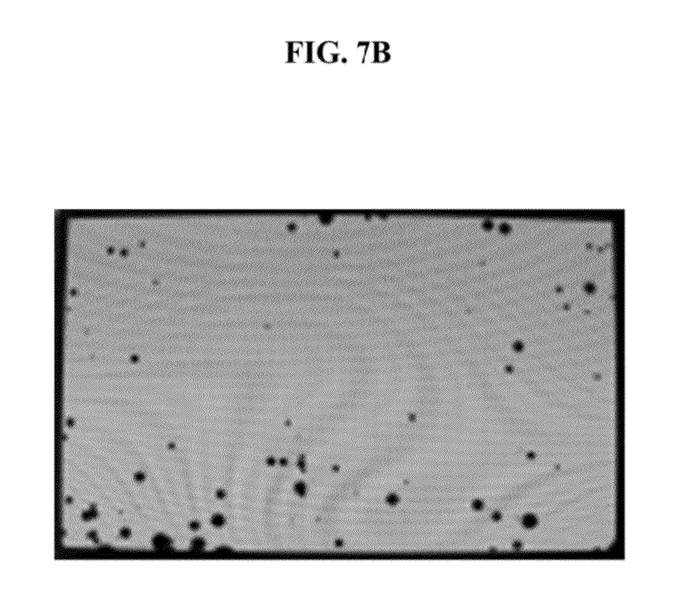

FIG. 7A illustrates an image of an organic light emitting diode (OLED) display turned on when 140 hours have passed after a second inorganic layer was formed in the case in which a first porous inorganic layer and a second inorganic layer were sequentially formed on the second pixel electrode. FIG. 7B illustrates an image of an organic light emitting diode (OLED) display when 410 hours have passed after a second inorganic layer was formed in the case in which a first porous inorganic layer and a second inorganic layer were sequentially formed on the second pixel electrode.

As shown in FIG. 7A and FIG. 7B, it is found that the size of the dark spots occurring near the particles is not increased, e.g., not substantially increased, as time passes under the high temperature (85° C.) and high moisture (85%) condition after the second inorganic layer 202 is deposited.

Without intending to be bound by this theory, this may be because the holes of the first porous inorganic layer 201 have covered the particles that are generated when or before the first porous inorganic layer 201 is deposited to reduce the possibility of and/or prevent permeation of moisture and oxygen into the side of the particles. When the size of the particles is less than the thickness of the deposited first porous inorganic layer 201, the first porous inorganic layer 201 covers the particles, and when the size of the particles is greater than the thickness of the deposited first porous inorganic layer 201, the first porous inorganic layer 201 surrounds the particle so the growth of the dark spots is very slow.

Accordingly, the organic light emitting diode display and the manufacturing method thereof reduce the stress of the layer by forming a thin film encapsulation layer by alternately providing a plurality of first porous inorganic layers and a plurality of second inorganic layers and minimize the growth rate of the dark spot by controlling permeation of external moisture and oxygen.

By way of summation and review, the OLED display may include an organic light emitting element composed of a hole injection electrode, an organic emission layer, and an electron injection electrode. The organic light emitting element may emit light by energy that occurs when excitons generated by a combination of electrons and holes in the organic emission layer enter the ground state from the exited state. The organic light emitting diode display may use such light emission to display images.

The organic light emitting element may be deteriorated due to, e.g., internal and external factors. Internal factors include, e.g., the organic emissive layer may be deteriorated under an atmosphere of oxygen from indium tin oxide (ITO) being used as an electrode material and an interfacial reaction between an organic layer and components of the organic emissive layer. The external factors include, e.g., external moisture and oxygen, and ultraviolet rays. The external oxygen and moisture may seriously influence the lifespan of the organic light emitting diode. As such, the organic light emitting diode may be packaged such that it is sealed from the outside in a vacuum-tight manner. The organic light emitting diode may be packaged using various methods.

For example, a thin film encapsulation (TFE) technique may be used in packaging the organic light emitting diode. With the thin film encapsulation technique, one or more of inorganic and organic layers may be alternately deposited on the organic light emitting diodes formed at the display area of the substrate. Therefore, the display area may be covered with a thin film encapsulation layer. When the organic light emitting diode display with such a thin film encapsulation layer is combined with a substrate that is formed with a flexible film, the OLED may be bent easily. This structure may be advantageous in forming a slim structure.

An organic layer of the thin film encapsulation layer may be used to efficiently mitigate stress of the organic light emitting diode display. However, the organic layer may also be used as a permeation path of moisture and oxygen. Further, when an inorganic layer is deposited over the organic layer, the inorganic layer may not be tightly adhered to the organic layer so it can become loose.

Embodiments, e.g., the exemplary embodiments discussed above, relate to an organic light emitting diode display and a manufacturing method thereof. Moreover, embodiments relate to an organic light emitting diode display to which a thin film encapsulation (TFE) configuration is applied, and a manufacturing method thereof. Embodiments may be realized by providing an organic light emitting diode display that reduces stress and reduces and/or prevents permeation of moisture and oxygen by applying a thin film encapsulation layer. Embodiments may reduce the stress of the layer by forming a thin film encapsulation layer by alternately stacking first porous inorganic layers and second inorganic layers, and minimizing the growth speed of the dark spot by controlling permeation of external moisture and oxygen.

Exemplary embodiments have been disclosed herein, and although specific terms are employed, they are used and are to be interpreted in a generic and descriptive sense only and not for purpose of limitation. While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display, comprising:
a substrate having a plurality of organic light emitting elements thereon; and
a thin film encapsulation layer on the substrate, the thin film encapsulation layer covering the organic light emitting elements,
the thin film encapsulation layer including a first porous inorganic layer and a second inorganic layer on the first porous inorganic layer.

2. The organic light emitting diode display of claim 1, wherein the first porous inorganic layer is made of silicon carbon nitride (SiCN) and the second inorganic layer is made of silicon nitride (SiN).

3. The organic light emitting diode display of claim 2, wherein the first porous inorganic layer is one of a plurality of first porous inorganic layers in the thin film encapsulation layer and the second inorganic layer is one of a plurality of second inorganic layers in the thin film encapsulation layer, and the plurality of first porous inorganic layers and the plurality of second inorganic layers are alternately stacked in the thin film encapsulation layer.

4. The organic light emitting diode display of claim 2, wherein a layer density of the first porous inorganic layer is about 1.4 g/cm³ to about 1.8 g/cm³.

5. The organic light emitting diode display of claim 2, wherein a layer density of the second inorganic layer about 2.0 g/cm³ to about 3.5 g/cm³.

6. The organic light emitting diode display of claim 2, wherein a refractive index of the first porous inorganic layer is about 1.5 to about 1.75.

7. The organic light emitting diode display of claim 2, wherein a thickness of the first porous inorganic layer is about 0.5 μm to about 1.5 μm.

8. The organic light emitting diode display of claim 2, wherein a thickness of the second inorganic layer is about 0.5 μm to about 1.5 μm.

9. A method for manufacturing an organic light emitting diode display, the method comprising:
forming a first porous inorganic layer that covers a plurality of organic light emitting elements on a substrate having the organic light emitting elements formed thereon; and
forming a second inorganic layer that covers the first porous inorganic layer.

10. The method of claim 9, wherein the first porous inorganic layer is made of silicon carbon nitride (SiCN) and the second inorganic layer is made of silicon nitride (SiN).

11. The method of claim 9, wherein the first porous inorganic layer is formed by mixing materials including silane (SiH₄), ammonia (NH₃), nitrogen (N₂), hydrogen (H₂), and acetylene (C₂H₂).

12. The method of claim 9, wherein the second inorganic layer is formed by mixing materials including silane (SiH₄), ammonia (NH₃), nitrogen (N₂), and hydrogen (H₂).
